(19) United States
(12) Patent Application Publication
(10) Pub. No.: US 2007/0287074 A1
(43) Pub. Date: Dec. 13, 2007

(54) Controlled ambient reticle frame

(75) Inventor: Sylvia D. Pas, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS, INCORPORATED

(21) Appl. No.: 11/450,446

(22) Filed: Jun. 12, 2006

(51) Int. Cl. A47G 1/12; G03F 1/14; G03B 27/62; G03F 1/00

(52) U.S. Cl. 430/5; 355/75; 428/14

(57) ABSTRACT

Embodiments provide a system and a method to control the gas ambient in a reticle frame system. The reticle frame system can include a first cross structure including a pellicle, a second cross structure substantially parallel to the first cross structure, a first side structure, and a second side structure. The second cross structure can include a reticle. An inlet frame can be coupled in one of the first and second side structures. At least one inlet passage can be configured through the inlet frame. An outlet frame can be coupled in the other of the first and second side structures. At least one outlet passage can be configured through the outlet frame. A frame filter can be positioned to cover one end of the outlet passage.

### FIELD OF THE INVENTION

This invention relates generally to reticle frame systems used in a lithographic process, and, more particularly, to reticle frame systems including inlet passages and outlet passages configured to actively control gas ambient within the reticle frame system. This invention further relates to a system and a method to reduce and eliminate contamination within the reticle frame system.

### BACKGROUND OF THE INVENTION

In the semiconductor industry, intricate designs or patterns of electronic chips are generally made using lithographic techniques, such as photolithography, X-ray lithography, or extreme ultraviolet (EUV) lithography. These techniques utilize a patterned reticle in-combination with certain systems to transfer patterns onto electronic chips. For example, in a photolithographic process, a patterned photomask (i.e. reticle) is used in combination with laser exposure systems to transfer patterns. The patterns typically possess extremely fine features and geometries. The presence of even tiny particles and other defects on the surface of the patterned reticle can interfere with the accurate reproduction-of the patterns on the target electronic chips.

One conventional solution to protect the reticle from physical and chemical contaminations is to develop reticle frame systems. In reticle frame systems, a pellicle membrane is applied to cover the reticle so that contamination falls on the pellicle membrane rather than the surface of the reticle. A frame is used to support the pellicle membrane at a sufficient distance above the reticle surface so that, for example, in a photolithographic process, any particles that fall upon the pellicle membrane lie outside the focal plane of the illuminating light, and so fail to interfere with the projected reticle patterns. The enclosure between the pellicle membrane and the reticle within the frame is defined as a pellicle space.

Problems arise when a conventional reticle frame system is subjected to significant air pressure differentials during air shipment. The significant air pressure differentials between the pellicle space and the exterior of the reticle frame system causes the volume of air in the pellicle space to expand or contract, thus causing the pellicle membrane and reticle surface to be damaged. Consequently, vent structures have been developed in the frame of the reticle frame system to equalize the air pressure differentials.

In addition, vent structures have also been used to-remove contaminants trapped within the pellicle space. Those contaminants may cause defects on the reticle during lithographic processes. For example, in photolithographic processes, high, energy lasers such as 365 nm i-line or 248 nm ultraviolet (UV) or deep-ultraviolet (DUV) are commonly used in the exposure stage. Such exposure from high energy lasers can catalyze the exposed environment and trigger certain undesired photochemical and thermal reactions in the pellicle space. These reactions can cause defects to form and grow on the surfaces of the components of the reticle frame system, eventually damaging the fidelity of the patterns transferred to the chips.

The formation and growth of defects resulting from the undesired photochemical and thermal reactions are affected by several factors, including the reticle frame system components, the photomask and silicon storage and fabrication environment, the exposure system environment, residuals from the cleaning of the reticle frame system components, or repetitive exposure to the laser light. For example, due to the presence of water vapor, ammonia, carbon dioxide, and sulfuric acid, which either have diffused into the pellicle space from the exterior environment or have been formed by degas or degradation of the system components or remained as a residue from the photomask fabrication process, defects may be formed during the laser exposure. It is also believed that the presence of air atmospheric gases such as oxygen in the exposure environment may cause defects such as haze formed on the reticle. In addition, oxygen and water vapor can absorb the laser light at a certain ultraviolet wavelength (e.g. 193 nm), thereby decreasing the light transmittance.

Vent structures (e.g. channels) in the frame have been used to control the gas ambient of the pellicle space using an inert gas such as nitrogen to discharge or displace contaminants and/or atmospheric gas from the pellicle space. These vent structures are constructed by forming passages penetrating through the frame and/or the adhesive layers used in mounting the frame to reticle frame system. In order to prevent the diffusion of small particles (e.g. smaller than 10 micrometers) into the pellicle space from the exterior of the reticle frame system, the vent structures take the form of tortuous or zigzag-shaped structures to trap the particles.

One conventional method used to control the gas ambient in the pellicle space uses pre-purging with an inert gas. When the reticle frame system is placed in a pre-purged enclosure, inert gas defuses from the enclosure into the pellicle space through the orifices. For example, the enclosure may be a projection printer machine enclosure for a photolithographic process. In this case, the inert gas defuses not only into the reticle frame system, but also into other instruments that the projection printer machine may include such as a light source, a projection lens, and a wafer or a die. Moreover, when the reticle frame system is being transferred between the projection printer machine enclosure and the storage enclosure, the path between these two enclosures may need to be pre-purged with inert gas. Putting the orifice-structured reticle frame system in pre-purged enclosures, however, complicates the process of controlling the gas ambient in the pellicle space.

More importantly, most conventional reticle frame systems with vent structures use passive air, which is sometimes not effective in removing contaminants trapped in the pellicle space of the reticle frame system.

Other problems for conventional reticle frame systems with vent structures arise due to organic contamination which may adhere to the surface of the reticle frame system components. In this case, the physical inert gas purging is not effective in reducing or eliminating the organic contaminants, which may cause defects on the reticle and eventually damage the patterns transferred to the chips.

### SUMMARY OF THE INVENTION

According to various embodiments, the present teachings include a reticle frame system including a first cross structure including-a pellicle, a second cross structure substantially parallel to the first cross structure, a first side structure, and a second side structure. The second cross structure includes a reticle or a backside cover. An inlet frame can be coupled in one of the first and second side structures. At least one inlet passage can be configured through the inlet frame. An outlet frame can be coupled in the other of the first and second side structures. At least one outlet passage can be configured through the outlet frame. A frame filter can be positioned to cover one end of the outlet passage.

According to various embodiments, the present teachings also include a system of controlling gas ambient in a reticle frame system. The system can include a gas source, an inlet regulator, a reticle frame system connected to the inlet regulator, wherein the inlet regulator connects to the gas source, and an outlet regulator further connected to the reticle frame system.

According to various embodiments, the present teachings further include a method of controlling gas ambient in a reticle frame system. In the method, a forced gas is provided to purge into the reticle frame system. A purging process including at least one physical purging, at least one chemical purging, and at least one inert gas displacement is provided with forced gas to control the gas ambient in the reticle frame system.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate one embodiment of the invention and together with the description, serve to explain the principles of the invention.

FIG. 1A shows a schematic diagram of a reticle frame system 100 in accordance with the present teachings.

FIG. 1B shows a cross-sectional view along the 1B-1B direction for the reticle frame system shown in FIG. 1A.

FIG. 2 is a block diagram showing an exemplary system 200 configured to reduce or eliminate contaminations in the reticle frame system in accordance with the present teachings.

FIG. 3 shows a flow diagram 300 for the purging module shown in FIG. 2 in accordance with the present teachings.

### DESCRIPTION OF THE EMBODIMENTS

Embodiments provide a system and a method to control the gas ambient in a reticle frame system. The reticle frame system can include a first cross structure including a pellicle, a second cross structure substantially parallel to the first cross structure, a first side structure, and a second side structure. The second cross structure includes a reticle. An inlet frame is coupled in one of the first and second side structures. At least one inlet passage is configured through the inlet frame. An outlet frame is coupled in the other of the first and second side structures. At least one outlet passage is configured through the outlet frame. A frame filter is positioned to cover one end of the outlet passage.

Reference will now be made in detail to the exemplary embodiments of the invention, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

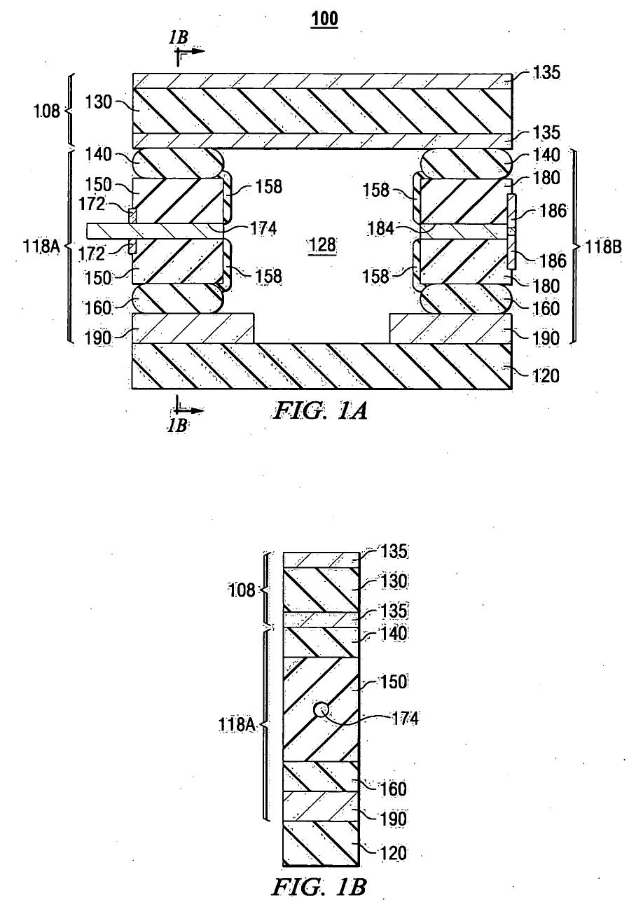

FIG.1A shows an exemplary schematic diagram of a reticle frame system 100 in accordance with the present teachings. FIG. 1B shows a cross-sectional view along 1B-1B direction for the reticle frame system shown in FIG. 1A. It should be readily obvious to one of ordinary skill in the art that the reticle frame system 100 depicted in FIGS. 1A-1B represents a generalized schematic illustration and that other components may be added or existing components may be removed or modified.

As shown in FIGS. 1A-1B, the reticle frame system 100 may include a pellicle structure 108, two side support structures 118A-B, and a reticle 120. The side support structures 118A-B can be configured to support the pellicle structure 108 and the reticle 120 in a substantially parallel plane. The pellicle structure 108, the two support structures 118A-B and the reticle 120 may also enclose a pellicle space 128.

The pellicle structure 108 may include a pellicle 130 with two layers of anti-reflective film 135. The pellicle 130 can be configured to provide a physical barrier to protect the reticle 120 from outside contaminants, such as, for example, particles or vapor outgassing. Accordingly, the reticle's lifetime can be extended, pattern fidelity can be retained, and the cost of ownership of the electronic chips can be decreased. The pellicle 130 can be a hard pellicle formed of, for example, synthetic or fused silica, or other similar materials. In various embodiments, the pellicle 130 can be formed of a soft transparent polymer, such as nitrocellulose, cellulose ester, fluorocarbon polymer or other similar materials.

The anti-reflective film 135 may be configured to be in contact with the pellicle 130. The anti-reflective film 135 may be configured to increase the transmittance of the laser light used in the exposure process of the photolithographic process and to improve the uniformity over the pellicle 130. The anti-reflective film 135 may be implemented with an inorganic material, such as calcium fluoride, or a polymer material, such as fluoropolymer, or other similar material. The anti-reflective 135 may be deposited or coated on either exposed surface of the pellicle 130.

The side support structure 118A can include a glue 140, an inlet frame 150, a liquid coating 158, and a mounting adhesive 160. The glue 140 may be an adhesive material configured to attach the pellicle structure 108 to one end of the side support structure 118 A. More particularly, the glue 140 may attach and secure the pellicle structure 108 to one end of the inlet frame 150.

The inlet frame 150 may be configured to support the pellicle structure 108. A connecter device 172 may be interspersed on one side of the inlet frame 150 to maintain an inlet passage 174.

The inlet frame 150 can be implemented with any material that is mechanically and chemically rigid, flat and stable when exposed to electromagnetic energy, for example, ultraviolet light, within a photolithographical system. Materials include, but are not limited to one or more of anodized aluminum alloy, stainless steel, plastic, silica, polyethylene, or other similar material. The inlet frame 150 may be a solid frame, a wire frame, a porous or non-porous frame, or any other frame. The inlet frame 150 in FIGS. 1A-1B may be formed in various shapes, such as, for example, a rectangular, polygonal, oval, or circular shape.

The connector device 172 may be positioned to introduce gases into the pellicle space 128 through the inlet passage 174 formed in the inlet frame 150. The connector device 172 may be connected to any gas source, which may provide forced gases. In various embodiments, the connector device 172 may be fabricated using the similar materials of the frame or any other material.

The inlet passage 174 may be configured to act as a channel (or pipe, conduit, etc.) to introduce forced gasses into the pellicle space 128. The inlet passage 174 may be any type of three-dimensional (i.e. 3-D) shape, such as a cylinder. The inlet passage 174 may be straight, arcuate, sinusoidal, etc.

The liquid coating 158 may be applied to an inner surface of the inlet frame 150 that interfaces with the pellicle space 128. The liquid coating 158 may be configured to capture particulate matter that may be present within the pellicle space 128. The liquid coating 158 may be used in conjunction with any adhesive or viscous material that may be ultraviolet resistant.

The mounting adhesive 160 may be any of adhesive materials configured to attach the other end of the side support structure 118A to the reticle 120 as shown in FIGS. 1A-1B.

The side support structure 118B can include a glue 140, an outlet frame 180, a liquid coating 158, and a mounting adhesive 160. The glue 140 may be an adhesive material configured to attach the pellicle structure 108 to one end of the side support structure 118B, that is, one end of the outlet frame 180 as shown in FIG. 1A.

The outlet frame 180 may be configured to support the pellicle structure 108. An outlet passage 184 may be interspersed through the outlet frame 180. A frame filter 186 may be positioned on one side of the outlet frame 180 and to cover one end of the outlet passage 184.

The outlet frame 180 may be implemented using the similar or different shapes or materials of the inlet frame 150 as described previously. The outlet frame 180 can be implemented with any material that is mechanically and chemically rigid, flat and stable when exposed to electromagnetic energy within a lithographic system. Such materials include, but are not limited to, one or more of anodized aluminum alloy, stainless steel, plastic, silica, polyethylene, or other similar material. The outlet frame 180 may be a solid frame, a wire frame, a porous or non-porous frame, or any other frame. The outlet frame 180 may include various shapes, such as, for example, a rectangular, polygonal, oval, or circular shape.

The outlet passage 184 may be configured to be a passageway, conduit, channel, pipe or other similar structure to vent gases from the pellicle space 128. The vented gas may contain atmospheric gas, residues, particulate contaminant, organic contaminant, or other contaminants. The outlet passage 184 may also be use to vent gas to equalize air pressure during transportation. The outlet passage 184 may be any shape, such as a cylinder or other similar 3-D shape. The outlet passage 184 may be configured to be substantially parallel, arcuate, and sinusoidal.

The frame filter 186 can be used to prevent particles from passing through the outlet passage 184 into the pellicle space 128. The frame filter 186 can be positioned at one end of the outlet passage 184, where the outlet passage 184 exits the outlet frame 180. The frame filter 186 can have a pore size that block particulates in the range of approximately 0.01 μm or greater and molecular contaminants in the range of approximately 0.001 μm or greater. In various embodiments, the frame filter may not necessarily be used.

The liquid coating 158 may be applied to an inner surface of the outlet frame 180 that interfaces with the pellicle space 128. The liquid coating 158 may be configured to capture particulate matter that may be present within the pellicle space 128. The liquid coating 158 may be used in conjunction with any adhesive or viscous material that may be ultraviolet resistant.

The mounting adhesive 160 may be any of adhesive materials configured to mount the other end of the side support structure 118B on the reticle 120 as shown in FIG. 1A.

The two side structures 118A-B can be mounted on the reticle 120. Release liners 190 can be disposed adjacent to the reticle 120 to contact with the side support structure 118A and the side support structure 118B, respectively. The release liner 190 facilitates removal of the side structures 118A-B. Accordingly, the release liner 190 may allow various components of the reticle frame system 100 to be cleaned or replaced. The release liner 190 may be-made of a polymer material and are known to those of ordinary skill in the art.

The reticle 120 may be a mask used in a lithographic process. The reticle 120 may be printed with a pattern of an electronic circuit or chip (not shown) to be produced. The reticle 120 can be made of, for example, synthetic silica, such as glass, or quartz.

In various embodiments, the reticle 120 may be replaced by a backside cover (not shown) during transportation. The backside cover may be used to seal the pellicle space 128 against airborne particles during transportation. The backside cover may then be removed before the reticle 120 may be configured to the reticle frame system 100.

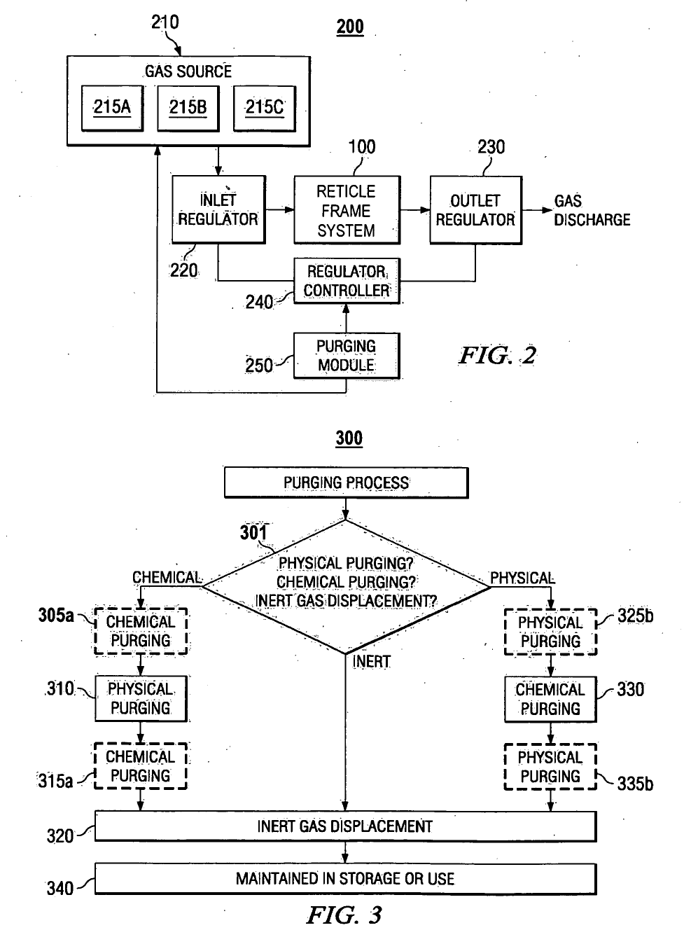

FIG. 2 is a block diagram showing an exemplary system 200 configured to reduce or eliminate defects from occurring on the reticle 120 as in FIGS. 1A-1B. As depicted in FIG. 2, system 200 can include a gas source 210, an inlet regulator 220, the reticle frame system 100, an outlet regulator 230, a regulator controller 240 and a purging module 250. The gas source 210 may be connected to the inlet regulator 220. The inlet regulator 220 may then be connected with the reticle frame system 100 through the connector device 172 (see FIG. 1A). The reticle frame system 100 may further be connected to the outlet regulator 230 through the outlet passage 184 (see FIG. 1A). The regulator controller 240 may be configured to control the inlet regulator 220 and/or the outlet regulator 230. The purging module 250 may provide a feedback loop from the gas source 210 to the regulator controller 240.

The gas source 210 may include one or more gas containers, for example, container 215A, 215B, and 215C as shown in FIG. 2. Each container may include different types of gases for different purpose, such as a physical purging, a chemical purging or an inert gas displacement. For example, container 215A may include any type of gas, such as oxygen (O₂), hydrogen (H₂), or argon (Ar), helium (He), nitrogen (N₂), or other inert gas, or a mixture of gases for the physical purging. Container 215B may include a gas with one or more chemically reactive species, such as atomic oxygen, oxygen (O₂), hydrogen (H₂), or other chemically reactive specie for the chemical purging. Container 215C may include a gas with one or more inert gases for the inert gas displacement, which may further include a circulation of the inert gas through the reticle frame system 100. The one or more inert gases may be substantially free of moisture, oxygen, nitrogen or any contaminants that can form haze during the exposure stage of lithographical processes. Accordingly, the one or more inert gases may be pure, dry and particle free and may include at least one pure dry particle free gas such as argon (Ar), helium (He), or other inert gas. The physical purging, the chemical purging and the inert gas displacement are further described below.

According to various embodiments, the gas source 210 may provide a forced gas into the reticle frame system 100. The gas source 210 may be a pressurized vessel such as a tank, a cylinder or some other vessel, a compressor or a blower to increase the pressure of the forced gas. Accordingly, the forced gas may be a pressurized gas that may be denser than atmospheric gas.

The forced gas may be routed into the reticle frame system 100 through the inlet regulator 220 as shown in FIG. 2. The inlet regulator 220 may be a control valve or similar functioning device. In some embodiments, the inlet regulator 220 may be manually controlled. In other embodiments, the inlet regulator 220 may be controlled by a semi or fully automated controller such as the regulator controller 240 as shown in FIG. 2.

The outlet regulator 230 may be configured to control the rate of gas being discharged from the pellicle space 128 of the reticle frame system 100 (see FIG. 1A). The outlet regulator 230 may be a control valve. In some embodiments, the outlet regulator 230 may be manually controlled. In other embodiments, the outlet regulator 230 may be controlled by a semi or fully automated controller such as the regulator controller 240 as shown in FIG. 2.

The regulator controller 240 may be further coupled to one or more sensors (not shown) that may be located in or coupled to the pellicle space 128 (see FIG. 1A). The one or more sensors may provide internal ambient information such as pressure and gas concentration data of the pellicle space 128. Based on the data provided by the sensors, the regulator controller 240 may direct the inlet regulator 220 or the outlet regulator 230 to either open or close controlling the rate of the forced gas and gas out of the pellicle'space 128.

The purging module 250 may connect the gas source 210 with the regulator controller 240 and may be located in or coupled to the regulator controller 240. The purging module 250 may provide a feedback loop from the gas source 210 to the regulator controller 240. For example, the purging module 250 may be used to control the physical purging, the chemical purging or the inert gas displacement for a purging process by opening or closing an according container (i.e. container 215A, 215B or 215C) of the gas source 210 via the regulator controller 240. In various embodiments, the purging module 250 may not be necessarily used. Such control of the purging process may be performed manually.

Accordingly, the purging process that may include the physical purging, the chemical purging, and the inert gas displacement may be implemented in various embodiments. The purging process may include the forced gas from the gas source 210. The flow rate of the forced gas may be controlled by the inlet regulator 220 manually. Alternatively, the inlet regulator may be controlled by the regulator controller 240. In various embodiments, the flow rate may be controlled in a low rate, for example, ranging from about 0.01 microliter per minute to about 10 milliliter per minute. In other various embodiments, the flow rate may vary during the purging process.

In various embodiments, the purging process with the forced gas may be used to purge away atmospheric gases, residues, particles, organic contaminants, or other contaminants contained in the pellicle space 128 after the reticle frame system 100 has been fabricated. The purging process may further be used to displace the pellicle space 128 with pure dry particle free inert gases for storage or use in manufacturing of reticle 120 (see FIG. 1A).

FIG. 3 illustrates a flow diagram 300 for the purging module 250 in accordance with yet another embodiment. It should be readily apparent to one of ordinary skill in the art that the flow diagram 300 depicted in FIG. 3 represents a generalized schematic illustration and that other steps may be added or existing steps may be removed or modified.

As shown in FIG. 3, the purging module 250 in the system 200 may be configured to display possible choices for purging, in step 301. The system 200 may be configured to implement the physical purging, the chemical purging, and/or the inert gas displacement.

The purging module 250 may be configured to implement a physical purging process which may purge away contaminants that may be physically removed by the pressurized gas from the gas source 210 (see FIG. 2). More specifically, the purging module 250 may be configured to select container 215A from the gas source 210. During the physical purging, the purging module 250 may cause the regulator controller 240 to open the inlet regulator 220 to purge gas from container 215A into the reticle frame system 100. The regulator controller 240 may then open the outlet regulator 230 to force the exit of the contaminated gases in the reticle frame system 100 to a discharge tank (not shown) or outside environment. Defects caused by crystals, residues, or other particulate contaminants that may be generated from fabrication components or fabrication environments, may be partially or completely removed by the physical purging.

The purging module 250 may be configured to implement the chemical purging process, which may “chemically” purge away contaminants such as organic contaminants using a chemical reaction. More specifically, the purging module 250 may be configured to select container 215B from the gas source 210 (see FIG. 2). During the chemical purging, the purging module 250 may cause the regulator controller 240 to open the inlet regulator 220 to purge gas from container 215B into the reticle frame system 100. The regulator controller 240 may then open the outlet regulator 230 to force the exit of the contaminated gases in the reticle frame system 100 to a discharge tank (not shown) or outside environment. Defects caused by the organic contaminants may be partially or completely removed by the chemical purging. Specifically, the forced gas from container 215B may include one or more chemically reactive species during the chemical purging. The one or more chemically reactive species may react with organic contaminants present in the pellicle space 128 of the reticle frame system 100 (see FIG. 1A) and convert the organic contaminants into gaseous components. More particularly, for example, atomic oxygen that may be produced at atmospheric pressure may be included in the container 215B as the chemical reactive specie. The atomic oxygen may readily react with most organic contaminants. The chemical reaction converts the organic contaminants into gaseous components, such as carbon monoxide, carbon dioxide, or water vapor. Such gaseous components may then be purged away from the pellicle space 128.

The purging modulate 250 may be configured to implement the inert gas displacement, which may displace any existing gas contained in the pellicle space 128 of the reticle frame system 100 (see FIG. 1A). More specifically, the purging module 250 may be configured to select container 215C from the gas source 210 (see FIG. 2). The purging module 250 may cause the regulator controller 240 to open the inlet regulator 220 to purge gas from container 215C into the reticle frame system 100. The regulator controller 240 may then open the outlet regulator 230 to force the exit of the gases in the reticle frame system 100 to a discharge tank (not shown) or outside environment. During this process, the one or more inert gases from container 215C of the gas source 210 may displace the existing gases contained in the pellicle space 128. The existing gases may include atmospheric gases such as nitrogen, oxygen, carbon dioxide, or water vapor that may cause the formation of haze or other defect on the reticle 120 in the subsequent exposure stage.

Turning to FIG. 3, in response to a user input, the purging module 250 may be configured to implement a physical purging, in step 310. In some embodiments a chemical purging may occur prior to the physical purging as in step 305a. In yet other embodiments, the chemical purging may occur after the physical purging as in step 315a. In also other embodiments, multiple physical purging or multiple chemical purging may be combined to be implemented by the purging module 250 (not shown). Subsequently, the purging module 250 may be configured to implement the inert gas displacement purging in step 320 with one or more pure dry particle free inert gases. As a result, in step 340, the pellicle space 128 of the reticle frame system 100 may be maintained by the pure dry particle free inert gas during storage or use in manufacturing such as a photolithographic process.

In response to a user input, the purging module 250 may be configured to implement a chemical purging, in step 330. In some embodiments a physical purging may occur prior to the chemical purging, in step 325b. In yet other embodiments, the physical purging may occur after the chemical purging, in step 335b. In also other embodiments, multiple chemical purging or multiple physical purging may be combined to be implemented by the purging module 250 (not shown). Subsequently, the purging module 250 may be configured to implement the inert gas displacement purging as in step 320 with one or more pure dry particle free inert gases. As a result, in step 340, the pellicle space 128 of the reticle frame system 100 may be maintained by the pure dry particle free inert gas during storage or use in manufacturing such as a photolithographic process.

In response to a user input, the purging module 250 may be configured to implement an inert gas displacement as in step 320 with one or more pure dry particle free inert gases. Thus, the pellicle space 128 of the reticle frame system 100 may be maintained by the pure dry particle free inert gas during storage or use in manufacturing such as a photolithographic process as in step 340. In this case, the physical purging or the chemical purging may not be necessarily needed prior to the inert gas displacement.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A reticle frame system comprising:
a first cross structure, wherein the first cross structure comprises a pellicle;
a second cross structure, wherein the second cross structure is substantially parallel to the first cross structure;
a first side structure; and
a second side structure, wherein one of the first and second side structures comprises at least one inlet passage and the other of the first and second side structures further comprises at least one outlet passage and the at least one outlet passage further comprises a filter.

2. The reticle frame system of claim 1, wherein the second cross structure comprises:
a reticle configured for one or more of transportation, storage, and manufacturing.

3. The reticle frame system of claim 1, wherein the second cross structure comprises a backside cover for transportation.

4. The reticle frame system of claim 1, wherein the one of the first and second side structures comprises an inlet frame configured with the at least one inlet passage configured to pass gases through the inlet frame.

5. The reticle frame system of claim 1, further comprises a connector device coupled to one end of the at least one inlet passage.

6. The reticle frame system of claim 1, the other of the first and second side structures further comprises an outlet frame, wherein the at least one outlet passage is configured through the outlet frame to vent gases.

7. A system of controlling gas ambient in a reticle frame system comprising:
a gas source;
an inlet regulator;
a reticle frame system connected to the inlet regulator, wherein the inlet regulator connects to the gas source; and
an outlet regulator further connected to the reticle frame system.

8. The system of claim 7, wherein the gas source comprises at least one pressurized gas.

9. The system of claim 7, wherein the gas source comprises one or more containers.

10. The system of claim 9, wherein the gas source comprises one or more containers, wherein the one or more containers comprises gases for at least one of a physical purging, a chemical purging or an inert gas displacement.

11. The system of claim 7, further comprises a regulator controller configured to control the inlet and outlet regulators.

12. The system of claim 11, wherein the regulator controller further comprises a purging module.

13. The system of claim 7, further comprises a connector device configured to connect the reticle frame system to the inlet regulator.

14. The system of claim 7, wherein the outlet regulator further connects to the reticle frame system through the outlet passage of the reticle frame system.

15. The system of claim 14, further comprises a filter configured on one end of the outlet passage.

16. A method of controlling gas ambient in a reticle frame system comprising:
providing a forced gas;
physically purging the reticle frame system with the forced gas;
chemically purging the reticle frame system with the forced gas; and
displacing the reticle frame system with the forced gas , wherein the forced gas comprises a forced inert gas.

17. The method of claim 16, wherein providing the forced gas comprises providing a controlled forced gas.

18. The method of claim 17, wherein providing the controlled forced gas comprises providing a low flow rate controlled forced gas.

19. The method of claim 18, wherein the low flow rate comprises a range from about 0.01 microliter per minute to about 10 milliliter per minute.

20. The method of claim 16, wherein the forced gas for physically purging comprises at least one of oxygen (O₂), hydrogen (H₂), or argon (Ar), helium (He), nitrogen (N₂), or other inert gas, or a mixture of gases.

21. The method of claim 16, wherein the forced gas for chemically purging comprises at least one chemically reactive specie.

22. The method of claim 21, wherein the at least one chemically reactive specie comprises at least one of atomic oxygen, oxygen (O₂), hydrogen (H₂), or other chemically reactive specie.

23. The method of claim 16, wherein displacing the reticle frame system further comprises circulating the forced inert gas through the reticle frame system.

24. The method of claim 16, wherein the forced inert gas for displacing the reticle frame system comprises at least one pure dry particle free inert gas.

25. The method of claim 24, wherein the at least one pure dry particle free inert gas comprises at least one of argon (Ar), helium (He), or other inert gas.

26. The method of claim 25, wherein the at least one pure dry particle free inert gas controls the gas ambient in the reticle frame system for storage or use in manufacturing.
